(19) United States
(12) Patent Application Publication
(10) Pub. No.: US 2009/0212397 A1
(43) Pub. Date: Aug. 27, 2009

(54) Ultrathin integrated circuit and method of manufacturing an ultrathin integrated circuit

(75) Inventor: Mark Ewing Tuttle, Meridian, ID (US)

Correspondence Address: Mark Tuttle, 1946 W. Rattlesnake Dr., Meridian, ID, 83646, US

(73) Assignee: Mark Ewing Tuttle, Meridian, ID (US)

(21) Appl. No.: 12/378,668

(22) Filed: Feb. 18, 2009

Related U.S. Application Data
(60) Provisional application No. 61/066,749, filed on Feb. 22, 2008.

(51) Int. Cl. H01L 29/34; H01L 21/461; H01L 21/77

(52) U.S. Cl. 257/618; 438/637; 438/612; 257/E29.108; 257/E21.483; 257/E21.598; 438/795

(57) ABSTRACT

A method of manufacturing an ultra thin integrated circuit comprises providing a substrate having a front side, a back side, and an edge extending from the front side to the back side; creating a defect layer in the substrate; forming semiconductor devices proximate the front side after creating the defect layer; and cleaving proximate the defect layer after forming the semiconductor devices. Other methods and apparatus are also provided.

### CROSS REFERENCE TO RELATED APPLICATION

This application claims priority to U.S. Provisional Patent Application Ser. No. 61/066,749 filed Feb. 22, 2008, naming Mark Ewing Tuttle as applicant, and titled Method of Forming Ultrathin ICs Including Non-continuous Defect Layers, and incorporated herein by reference.

### TECHNICAL FIELD

The technical field comprises solid state integrated circuits. The technical field also comprises stacked integrated circuits, and solid state backside illuminated image sensors and methods.

### BACKGROUND

Many types of integrated circuits, including RFID, DRAM, Flash, microprocessors, imagers, and gate arrays, may benefit by thinning the final integrated circuit substrate to allow the integrated circuit to fit in a smaller package. Portable electronic consumer products, such as cell phones, music players, cameras, and video cameras benefit by being compact and small. Smaller electronic components, such as packaged integrated circuits, allow the construction of smaller electronic products.

There are situations where combining multiple integrated circuits into one package may provide advantages in higher capability, higher performance, and a reduction in the number of total components, such as stacking sixteen 1 gigabit Flash memory dice into one package to form an 2 gigabyte Flash memory component, or stacking a CMOS image sensor on an image sensor controller integrated circuit in one package. The stacking of multiple dice into an integrated circuit package becomes difficult due to the long distances required for wire bonding, and the size of the package becomes very large compared to a single integrated circuit package, minimizing the advantage of multiple integrated circuits in one package. Thinning of the individual integrated circuits by grinding the substrate has been used to thin the integrated circuit substrates from a standard thickness for 300 mm silicon wafers of 775 um down to about 100 um. Two major limitations of this grinding technology are the yield loss from breakage, and the uniformity of substrate removal. The breakage increases as more material is removed, and successfully grinding below 100 um is very difficult for this reason. Also, for a grinding substrate removal process, the percentage variation in thickness uniformity across a substrate may increase as the amount of material removed is increased. When grinding to a thickness less than 100 um, it becomes difficult to tightly control thickness uniformity across the substrate.

It is desirable for some applications, such as an RFID label, that the electronic product be somewhat flexible. Thinning a silicon integrated circuit below 100 um provides a small level of flexibility without breakage, and further decreasing the thickness provides an even more flexible component.

The electrical performance of multiple integrated circuits in one package may be improved by thinning the dice to allow shorter wire bonding wires or through-substrate vias which are used to electrically connect the dice. The parasitic electrical parameters of the interconnecting conductors, such as resistance, capacitance and inductance affect the electrical performance of the integrated circuits, and shorter conductors reduce the negative effect of the interconnect parasitic parameters.

Solid state image sensors are useful in cameras, including those in mobile phones, movie cameras, and other imaging devices. Examples of image sensors include CCD (charge coupled device) image sensors and CMOS (complementary metal oxide semiconductor) image sensors. Image sensors are based on a two dimensional array of pixels. Pixels are defined by sensing elements that are each capable of converting a portion of an optical image into an electronic charge or signal. These electronic signals are used to regenerate the optical image, such as on a display. A CCD image sensor has charges transferred from every pixel to a limited number of output nodes for conversion to voltage. CMOS image sensors have charge-to-voltage conversion for each pixel. CCD image sensors include metal-oxide-silicon capacitors that are formed very close to one another, with charge carriers stored and transported into the metal-oxide-silicon capacitors. CMOS image sensors are based on CMOS technology, which uses control circuits and signal processing circuits as peripheral circuits and employs MOS transistors corresponding to the number of pixels, for switching, wherein the output is detected using the MOS transistors. See, for example, U.S. Pat. No. 5,841,126 which is incorporated herein by reference.

CMOS image sensors may be driven more easily than the CCD image sensors, and may be advantageous in terms of minimized modules because signal processing circuits can be integrated into one chip.

Smaller pixels result in higher resolution, smaller devices, and lower power and cost. As pixel sizes shrink in image sensors, however, performance or image quality are sometimes degraded.

Front side illuminated CMOS image sensors suffer from drawbacks. The various metal layers crossing on top of a front illuminated sensor limit the light that can be collected in a pixel. The amount of light that can be collected in a pixel is referred to as “fill factor.” Other drawbacks to front side illuminated image sensors include reduced photo-response, low short and long wavelength quantum efficiency (QE) for blue photons and near-infrared (NIR) wavelengths, and interference fringing from thin passivation and interlayer dielectrics.

Solid state imagers, such as CMOS and CCD imagers, may benefit significantly by back side illumination. This is particularly important for CMOS imagers because they have additional circuitry in every pixel that blocks incoming light during front side illumination creating optically dead regions. In addition to the transistors and metal connections within a pixel, metal bus lines connect to each pixel from the periphery, which also block incoming light for front side illumination, as well as create undesirable optical effects such as light scattering, vignetting, diffraction, and non-symmetrical interactions between pixels. This problem is becoming larger because the general trend is for pixel size to continue to shrink with future generations, and this makes a given dead space a larger percentage of the pixel and thus requires smaller transistor device sizes to compensate, which may hurt overall imager performance. The front side circuitry also causes topography variations, which may cause problems with the formation of subsequent layers of color filters, microlenses, and passivation.

Back side illumination solves these front side illumination problems by providing unblocked access of the incoming photons to each pixel, which results in a high fill factor. Back side illumination provides a direct path for light to travel into the pixel, avoiding light blockage by the metal interconnect and dielectric layers on the top-side of the sensor die. This is because back side illuminated imagers have active pixel circuitry, such as electrodes and gates, arranged on the front surface of each substrate. Back side illumination also allows more efficient front side layouts of circuitry to optimize the charge collection and transfer by allowing more devices per pixel, or larger devices to optimize charge transfer performance, without having to deal with dead regions caused by larger blocking structures.

A further advantage of back side illumination is that typically an expensive epi layer, required for front side illumination structures, is not required for back side illumination structures. Epitaxy or epitaxial growth is the process of providing a thin layer of material over a substrate. In semiconductors, the deposited film is often the same material as the substrate but may have a different doping type or level. The deposited layer is known as an epi layer. This is not an electrical requirement for back side illumination structures. Thus, less expensive substrates without an epi layer may be used.

A fundamental limitation with respect to building back side illumination imagers is the technology required to thin the substrate uniformly to a desired thickness. The substrate needs to be thinned in order to allow the photons to travel to the photo-sensitive area. Another difficulty is in handling and packaging these extremely thin substrates. An academic method to build and test back side illumination for imagers has been published in an article by B. Pain, T. Cunningham, S. Nikzad, M. Hoenk, T. Jones, B. Hancock, and C. Wrigley, titled “A Back-Illuminated Megapixel CMOS Image Sensor”, from the IEEE Workshop on Charge-Coupled Devices and Advanced Image Sensors, Karuizawa, Japan, Jun. 9-11, 2005, published by Jet Propulsion Laboratory, National Aeronautics and Space Administration, and incorporated herein by reference. However, this method is not suitable for high volume production, low cost, high reproducibility, or wafer level packaging. The method described was performed on an individual die with wet chemical etching. It is very difficult to control the critical uniformity and final thickness of the photon collecting region using such a method.

### SUMMARY

Various embodiments provide a method of manufacturing ultrathin, less than 100 um thick, integrated circuits, the method including providing a substrate having a front side, a back side, and an edge extending from the front side to the back side; creating a defect layer in the substrate, the defect layer having at least one edge which does not intersect the edge of the substrate; defining a semiconductor device proximate the front side after creating the defect layer; and cleaving proximate the defect layer after defining the semiconductor device.

Some aspects provide methods of manufacturing integrated circuit substrates which are less than 100 um thick with high yield, high throughput, and high precision and uniformity in wafer form. Various embodiments integrate wafer level packaging which provides for stacking integrated circuits into packages which are higher capability and higher performance compared with packages produced by current processing and packaging methods which utilize grinding of the substrate.

Various aspects provide methods of manufacturing integrated circuit substrates with high yield and high precision and uniformity in wafer form which are less than 100 um thick and capable of flexing without breaking.

Yet other aspects provide methods comprising providing a substrate having a front side and a back side, and an edge extending from the front side to the back side; implanting an ion to create a defect layer in the substrate, the defect layer having at least one edge which does not intersect the edge of the substrate; forming active MOS devices in the substrate to define an integrated circuit; forming through-substrate vias from the front side; depositing insulators in the vias; depositing conductors in the vias; removing excess conductor and insulator from the front side; performing metal deposition and patterning on the front side; covering the metal with a passivation layer; patterning bond pad openings and forming bumps on the bond pads; at least partially encapsulating the front side; abrading the edge with an abrasive knife edge at the defect layer and performing cleavage; smoothing the new back side surface and making the vias flush with the new back side surface; forming an electrically insulating coating on the back side; and providing openings in the insulating coating to allow contact to the through-substrate vias.

Various embodiments provide methods of manufacturing back side illumination structures with high precision and uniformity in wafer form. Various embodiments integrate wafer level packaging into the back side illumination structures to achieve low cost and high throughput. In addition to providing the benefits of wafer level back side illumination processing and structures, various embodiments replace current processing and packaging methods which require contact to the bond pads through the back side of the substrate.

Some aspects provide a method of manufacturing a back side illuminated imager device, the method including providing a substrate having a front side, a back side, and an edge extending from the front side to the back side; creating a defect layer in the substrate, the defect layer having at least one edge which does not intersect the edge of the substrate; defining an image array proximate the front side after creating the defect layer; and cleaving proximate the defect layer after defining the image array.

Other aspects provide a method of manufacturing a back side illuminated imager device, the method comprising providing a substrate having a front side, a back side, and an edge extending from the front side to the back side; implanting an ion to create a defect layer in the substrate, the defect layer having at least one edge which does not intersect the edge of the substrate; defining an image array proximate the front side, wherein the imager is configured to receive light from the back side; and forming a transparent conductive layer on the backside.

Yet other aspects provide a method comprising providing a substrate having a front side and a back side, and an edge extending from the front side to the back side; implanting an ion to create a defect layer in the substrate, the defect layer having at least one edge which does not intersect the edge of the substrate; forming active MOS devices in the substrate including devices to define an integrated circuit array; forming through-substrate vias from the front side; depositing insulators in the vias; depositing conductors in the vias; removing excess conductor and insulator from the front side; performing metal deposition and patterning on the front side, to provide; covering the metal with a passivation layer; patterning bond pad openings and forming bumps on the bond pads; at least partially encapsulating the front side; abrading the edge with an abrasive knife edge at the defect layer and performing cleavage; smoothing the new back side surface and making the vias flush with the new back side surface; forming an antireflective coating on the back side; and providing openings in the antireflective coating to allow contact to the through-substrate vias.

Another aspect provides a method comprising a substrate having a front side, a back side, and an edge extending from the front side to the back side; creating a first defect layer in the substrate, the first defect layer having at least one edge which does not intersect the edge of the substrate; defining a semiconductor device proximate the front side after creating the defect layer; creating a second defect layer in the substrate, the second defect layer being substantially in the same plane as the first defect layer, and having at least one edge intersecting the edge of the substrate; and cleaving proximate the second defect layer.

### BRIEF DESCRIPTION OF THE VIEWS OF THE DRAWINGS

FIG. 1 is a schematic cross-sectional representation of a CMOS imager pixel using front side illumination.

FIG. 2 is a diagrammatic cross-sectional representation of a pixel using back side illumination.

FIG. 3 is a diagrammatic cross-sectional representation of an integrated circuit die after a front side encapsulation, in accordance with various embodiments.

FIG. 4 is a diagrammatic cross-sectional representation of an integrated circuit die after a partial front side encapsulation, in accordance with various embodiments.

FIG. 5 is a diagrammatic top view of the integrated circuit die of FIG. 3 after a front side encapsulation, in accordance with various embodiments.

FIG. 6 is a diagrammatic top view of the integrated circuit die of FIG. 4 after a partial front side encapsulation, in accordance with various embodiments.

FIG. 7 is a diagrammatic cross-sectional representation of an integrated circuit die with a front side stiffener, in accordance with various embodiments.

FIG. 8 is a diagrammatic cross-sectional representation of a singulated integrated circuit with the front side mounted against a printed circuit board, in accordance with various embodiments.

FIG. 9 is a diagrammatic cross-sectional representation of a die showing an implantation processing step.

FIG. 10 is a diagrammatic cross-sectional representation of the die of FIG. 9 at a subsequent processing stage.

FIG. 11 is a diagrammatic cross-sectional representation of the die of FIG. 10 at a subsequent processing stage.

FIG. 12 is a diagrammatic cross-sectional representation of an imager die with added metal, in accordance with various embodiments.

FIG. 13 is a diagrammatic side view showing a substrate, bonded to a handler substrate, and an abrasion tool in accordance with various embodiments.

FIG. 14 is a diagrammatic side view showing a substrate, bonded to a handler substrate, being operated on by the abrasion tool of FIG. 13.

FIG. 15 is a diagrammatic side view showing a substrate, bonded to a handler substrate, being operated on by a cutting tool, in accordance with various embodiments.

FIG. 16 is a diagrammatic side view showing a substrate which will have an additional doped semiconductor layer, in an intermediate processing step, in accordance with various embodiments.

FIG. 17 is a diagrammatic side view showing a substrate having a backside conductive layer, in accordance with various embodiments.

FIG. 18 is a diagrammatic cross-sectional representation of a substrate showing an ion implantation processing step, in accordance with various embodiments.

FIG. 19 is a diagrammatic cross-sectional representation of a substrate showing an ion implantation processing step, in accordance with various embodiments.

FIG. 20 is a diagrammatic top view of a substrate showing a masking structure prior to an ion implantation processing step, in accordance with various embodiments.

FIG. 21 is a diagrammatic top view of a substrate showing a masking structure prior to an ion implantation processing step, in accordance with various embodiments.

FIG. 22 is a diagrammatic cross-sectional representation of a substrate showing a masking structure prior to an ion implantation processing step, in accordance with various embodiments.

FIG. 23 is a diagrammatic cross-sectional representation of the substrate of FIG. 22, showing an ion implantation processing step, in accordance with various embodiments.

FIG. 24 is a diagrammatic cross-section of a completed stacked integrated circuit structure, in accordance with various embodiments.

FIG. 25 is a diagrammatic cross-section of a completed imager die in accordance with some embodiments.

FIG. 26 is a block diagram of a camera in accordance with various embodiments.

### DETAILED DESCRIPTION OF THE ILLUSTRATED EMBODIMENTS

This specification provides a detailed description for thinning semiconductor integrated circuit substrates wherein the integrated circuit that is manufactured performs at least one function selected from the group consisting of microprocessor, memory, radio frequency identification (RFID), gate array, and image sensor.

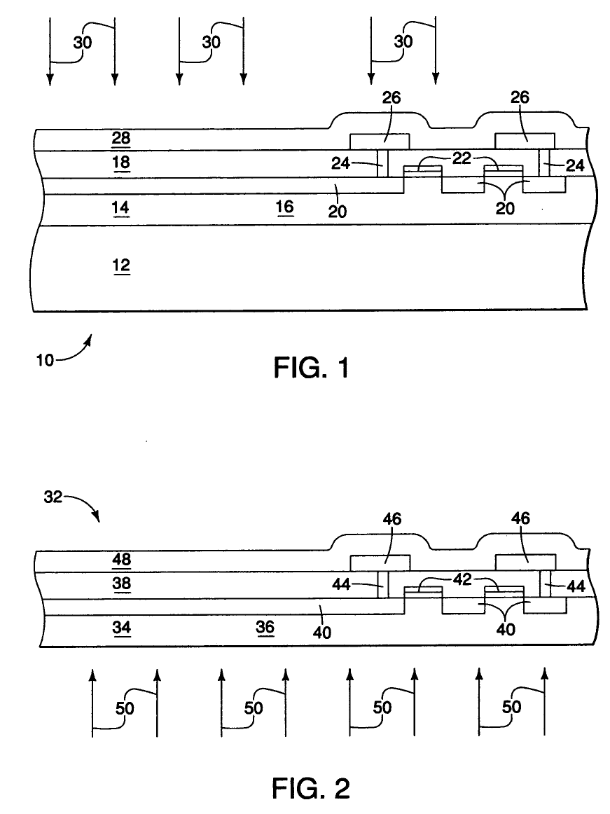

FIG. 1 is a cross-sectional diagrammatic representation of a prior art CMOS imager pixel 10 using front side illumination. A substrate 12 (e.g., a P+ substrate) is provided, there is an epi layer 14 over the substrate (e.g., a P− epi layer), a collection region 16, and a dielectric 18 over the epi. Reference numeral 20 points to source/drain regions (e.g., N+ material) of transistors, reference numeral 22 points to transistor gates, reference numeral 24 points to a contact, and reference numeral 26 points to a metallization layer. A passivation layer 28 is provided over the dielectric 18 and metallization layer 26. Arrows 30 indicate incoming light.

FIG. 2 is a cross-sectional diagrammatic representation of a prior art CMOS imager pixel 32 using back side illumination. A substrate 34 (e.g., a P− substrate) is provided, a collection region 36 is defined, and a dielectric layer 38 is provided over the substrate 34. Reference numeral 40 points to source/drain regions, reference numeral 42 points to transistor gates, reference numeral 44 points to contacts, and reference numeral 46 points to a metallization layer. A passivation layer 48 is over the dielectric 38 and metallization layer 46. Arrows 50 indicate incoming light.

This specification includes three parts, the first dealing primarily to the front side of the substrate to address the handling and packaging issues, the second part dealing primarily with forming the thin back side of the substrate, and the third part dealing primarily with the integration of the first two parts and the addition of methods and structures to form a completed and packaged integrated circuit. The individual methods and apparatus taught in these three parts may be combined advantageously in any desired sub-combination, depending upon requirements for cost, functionality, and performance.

### Part 1, Front Side

Various embodiments provide methods to integrate a front side handling structure prior to generating a thinned substrate, and resulting apparatus. Such a structure is, in various embodiments, also utilized as a wafer level package structure, thus reducing processing steps, materials used, build time, and cost.

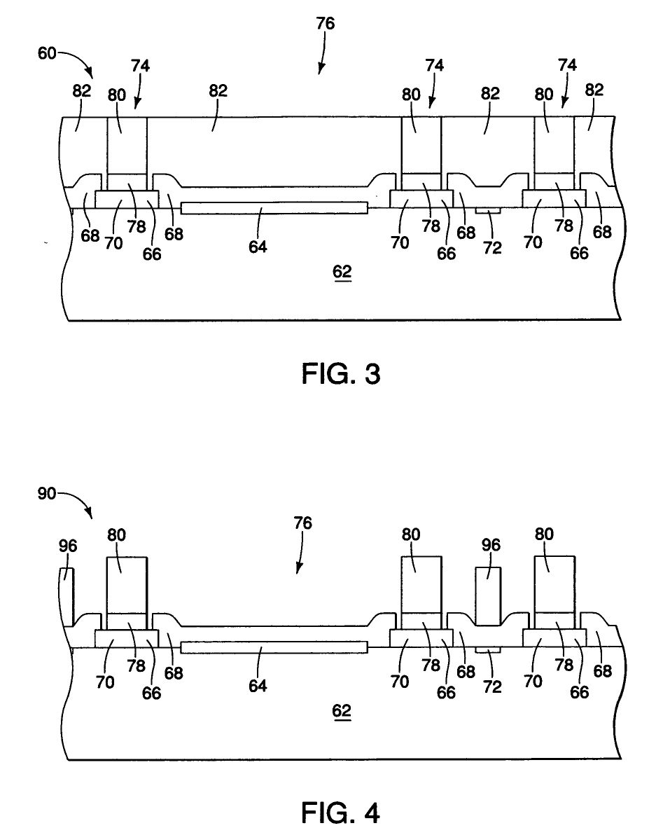

CMOS and bipolar integrated circuit processing steps include oxidation, patterning, etching, and other semiconductor processing steps on a silicon substrate 62 (see FIG. 3) to form active MOS or bipolar transistor devices in the silicon. In the illustrated embodiment, the substrate 62 is a P− substrate. Other substrate types are possible. In the case of an imager, or memory integrated circuit, these devices are often configured in an array 64 (see FIG. 3) of individual pixels, or memory cells, containing MOS or bipolar devices. After high temperature device process steps such as oxidation and diffusion are completed, a dielectric 38 (see FIG. 2) is formed on the substrate 62 with vias (openings) contacting the silicon device terminals, and filled with conductive material 44 such as tungsten, titanium nitride, or copper. An interconnect system of metallization 46 (see FIG. 2) or 70 (see FIG. 3) including aluminum, copper, tantalum or other conductive materials connects the devices on an upper level. A final passivation dielectric 48 (see FIG. 2) or 68 (see FIG. 3), such as silicon dioxide, silicon nitride, or combinations, is formed, if desired, on top of the interconnect metallization to prevent damage to the metallization 46 or 70. Openings in the passivation are provided at bond pads to allow electrical connection to the integrated circuit. In addition, saw streets 72 (see FIG. 3) are provided on the substrate to provide regions for sawing through the substrate for eventual separation of the individual integrated circuit chips. The saw street 72 may have some of the substrate, or dielectric, or interconnect metallization removed during processing to minimize the amount material that needs to be cut during the sawing process, and to prevent cracking.

From this point, in various embodiments, a bump 74 (see FIG. 3) is then placed on the bond pads (part of metallization 70) on the front side 76. This may be done by conventional electroplating or electroless plating technology to form a bump such as Cu or Ni/Au, by placing a solder ball on the pad, by wire bonding ball bumps, by extending the bond wire from the ball bump, or by other bumping technology known in the art. FIG. 3 shows a bump 74 that includes Ni 78 and Au 80 and is a Ni/Au bump; however, other types of bumps 74 may be employed.

The bump height may be as tall as the final front side package thickness, as shown in FIG. 3. The bump height may be from 20 to 3000 μm (micrometers) thick. In alternative embodiments, the bump may be recessed or protruding from the final package material depending, for example, upon the printed circuit board attachment technology used. In some embodiments, a front side thickness of about 300 μm is used.

At this point in the process flow, there are three variations, like reference numerals indicating like components.

In the embodiment shown in FIG. 3, an integrated circuit die or substrate 60 receives a complete front side encapsulation 82 using, for example, quartz filled epoxy or low expansion polymer to minimize the coefficient of expansion mismatches to the silicon, in transfer molding or film assisted molding processes. The molding process may allow the tops of the bumps to be exposed after the molding, however. If the encapsulation covers over the tops of the bumps, the bumps may be exposed later by a simple grind back process. Other materials such as polyimides, silicones, polyurethanes, as well as other methods of coating, such as puddle, spin-on, spray coating, plasma spray, and other techniques known in the art of coating and encapsulation may be used.

In the embodiment shown in FIG. 4, an integrated circuit die or substrate 90 receives a partial front side encapsulation. In the illustrated embodiment, the partial encapsulation uses quartz filled epoxy or low expansion polymer materials in the form of a circular ring around the substrate edge and/or in the form of window frames 96 covering the saw streets 72. The partial encapsulation 96 may cover the bond pad bumps 78/80 of each integrated circuit on the substrate, if the bumps are later exposed by removal of at least a portion of the frame. This framework may be formed by techniques such as epoxy molding, direct write polymer dispense system, or photolithography of a thick material such as photosensitive dry film, or by a 3-dimensional construction such as stereolithography. This framework is shown in a cross-section of an integrated circuit die at this point of the process in FIG. 4. After subsequent back side thinning, which is able to be accomplished because of the support of the front side framework acting as a stiffener and support structure, the integrated circuit device region may be left as a free membrane, to avoid any deformation due to the coefficient of expansion mismatch between the silicon and a full epoxy encapsulation. Alternatively, the volume inside the framework may be filled with an encapsulant, using dam and fill or molding techniques, or other methods such as spin-on, spray coating, plasma spray, and other techniques and materials known in the art of coating and encapsulation may be used.

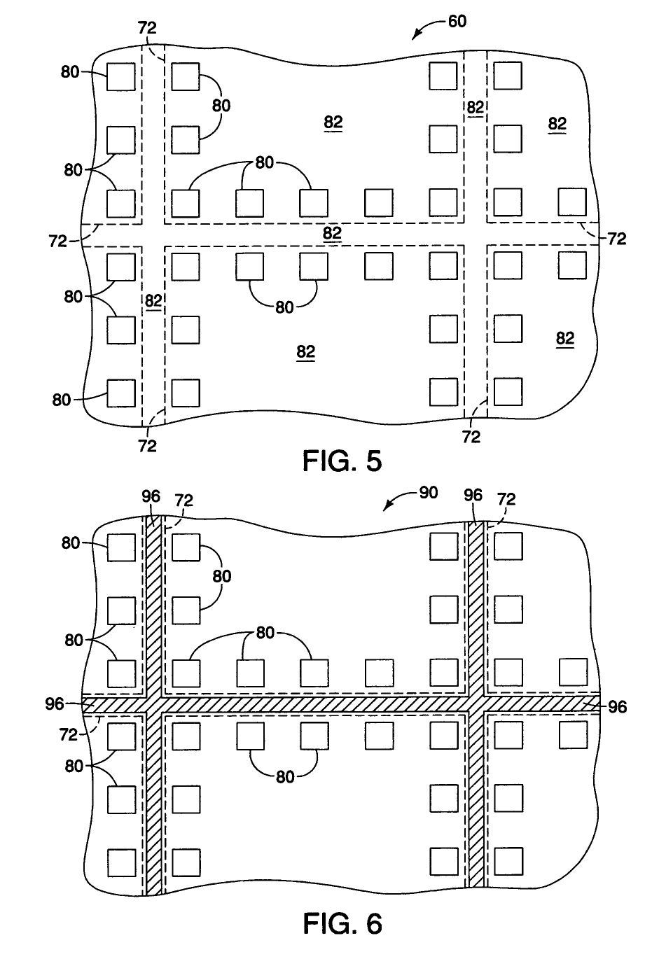

FIG. 5 is a top view of a substrate 60 showing a complete front side encapsulation 82. FIG. 6 is a top view of a substrate 90 showing a partial front side encapsulation 96 defining window frames over the saw streets 72.

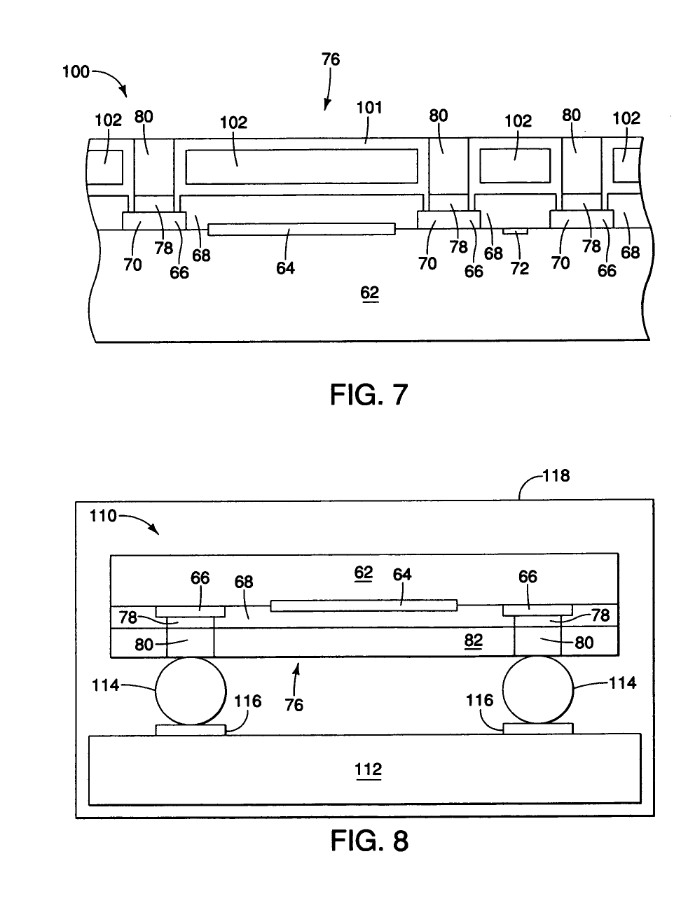

In the embodiment shown in FIG. 7, an integrated circuit substrate or die 100 may be bonded to a stiffener 102, such as an oxidized silicon substrate with holes etched or laser drilled over the bond pads 66. The stiffener 102 may be placed after the formation of the bumps 78/80. However, the stiffener 102 is most advantageously used as a self-aligned mask for the plating of the bond pads, or for placement of the solder balls. In addition, wire bond bumps may be placed after the stiffener 102 is in place, with the bump or wire extending from below to above the surface of the stiffener 102. In the illustrated embodiment, the thickness of this stiffener 102 is between 50 μm and 3000 μm. More particularly, in some embodiments, the stiffener 102 is about 300 μm thick. The stiffener 102 is attached to the oxide covering the metal, except where the oxide is open at the bond pads 66, on the front side of the integrated circuit substrate by oxide to oxide bonding, which is known in the art and may be achieved below 400 C, or attached by high temperature tolerant adhesives. Alternatively, the stiffener 102 could be a solid silicon wafer which is oxidized, and then bonded to the oxide surface without holes to the bond pads 66. Subsequent patterning and etching of the silicon and the oxide opens the bond pads 66. An insulator is then deposited and patterned to open the bond pads 66. FIG. 7 shows a cross-section of an integrated circuit die with a silicon stiffener 102 attached and the plated bumps 78/80 over the bond pads 66. Reference numeral 101 indicates oxide. The use of silicon material is an effective choice due to its coefficient of expansion matching the traditional silicon integrated circuit substrate; however, other materials such as quartz, glass or polymers are used in alternative embodiments.

This completes the description of the embodiments for the front side packaging and handling structures; however, for handling purposes through the back side processing steps, it is generally preferable to delay construction of the final bump connection structures, such as solder for attachment to printed circuit boards, or other integrated circuits, until all other processing and packaging steps are completed, so that a relatively flat and planar surface is available for handling.

An integrated circuit, such as a back side illuminated imager, 110 may ultimately be singulated from a die and mounted, as shown in FIG. 8, with the front side 76 adjacent a printed circuit board 112, flexible circuit, or stacked on another integrated circuit. In FIG. 8, solder balls 114 or other attachment structures electrically couple the bumps 80 to metal traces 116 of the circuit board 112. This structure is then, in some embodiments, integrated with a housing 118 containing optical elements (not shown). In some embodiments, a cell phone includes the housing 118 and the imager 110 is supported by the housing 118 along with other typical cell phone components.

### Part 2, Back Side

The thinning of the back side overburden material to form a back side illuminated imager has been reported using grinding and polishing, chemical etching, or a combination of the two (see, for example, U.S. Pat. No. 6,169,319 to Malinovich et al., incorporated herein by reference), and such methods may be used in conjunction with the front side embodiments described above in connection with FIGS. 3-7, in some embodiments. However, rather than eroding the back side material, various embodiments provide methods of exfoliation to provide a very thin, reproducible, uniform, cost effective, and smooth surface for the formation of thin integrated circuits, including back side illuminated imagers.

The removal of large amounts of substrate material to form an ultrathin integrated circuit substrate (less than 100 um), and the thin collection region required for back side illumination is very difficult to control. A 200 mm diameter silicon wafer, for example, is typically 725 μm thick. This thickness is for structural reasons during processing. It becomes difficult to handle a wafer under 500 μm thick for conventional semiconductor processing equipment. 300 mm diameter silicon wafers, which are often used to lower processing costs by increasing the wafer area, are even thicker at a standard thickness of 775 μm. The silicon thickness of a flexible RFID integrated circuit is less than 100 um. The silicon thickness of the absorbing layer required for adequate CMOS imager performance is below 15 μm, and may be as thin as 0.2 μm in some embodiments. The uniformity of substrate removal, the absolute thickness control, and the surface roughness need to be controlled precisely for variation from wafer to wafer, variation within a wafer, and variation on each individual integrated circuit die. This is extremely difficult to do with current methods of grinding, polishing, and/or etching when many hundreds of micrometers of material must be removed. A better method to accomplish the formation of an ultrathin integrated circuit substrate or optimized back side illuminated image sensor will now be provided.

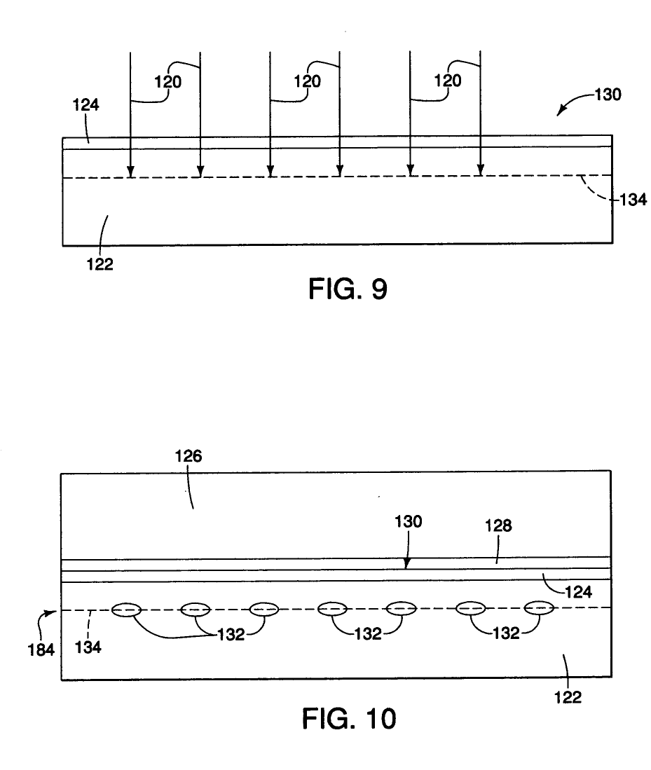

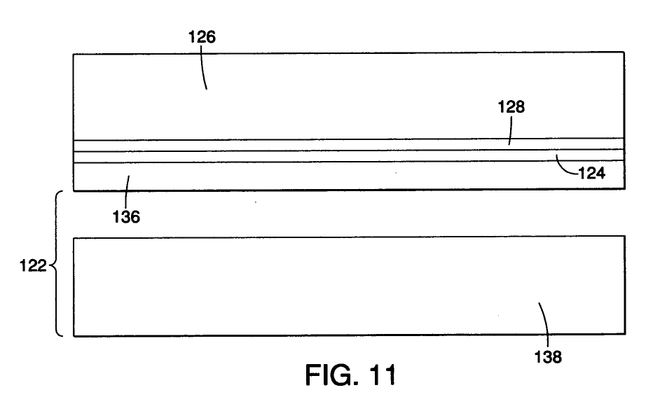

There is a general technique known as ion cutting for cleaving substrates by the implantation of a high dose of hydrogen 120 (see FIG. 9) into the first surface 130 of a first substrate 122. Reference numeral 124 indicates an oxide layer. Then (see FIG. 10), a handler substrate 126, having an oxide layer 128, is bonded onto the first surface 130 of the first substrate. Heat above 500 C is applied to form internal microbubbles 132. The microbubbles 132, in conjunction with the rigidity supplied by the bonded handler substrate 126, create a separation along a defect layer 184, for exfoliation of the first substrate 122, at a uniform depth 134 controlled by the depth of the hydrogen implantation. FIG. 11 shows an exfoliated portion 136 separated from portion 138 of original substrate 122.

Such an ion cutting technique is described, for example, in U.S. Pat. No. 5,374,564 to Bruel, incorporated herein by reference. This substrate ion cutting technique cannot readily be directly applied to an integrated circuit substrate because the thinning of the substrate must take place after the semiconductor device processing is complete. The standard ion cutting of an integrated circuit at that point in the process causes problems for many reasons including, for example, the high temperature required for microbubble formation and exfoliation, the damage caused by high energy implantation through live CMOS devices, the need for a continuously bonded stiffener, which prevents access to the bond pads on the front side of devices, the need to perform the three step implant/stiffener/heat cleaving process sequentially with no other thermal steps in between, and the variation in materials and variation of the thickness of materials during the implantation. Also, after the interconnect metallization has been deposited in an integrated circuit substrate process, the processing temperatures are kept below 500 C to avoid changes in electrical device performance and issues with recrystallization, roughness, and interdiffusion of the metals. In addition, although hydrogen is generally a beneficial element for semiconductor processing by passivating defects and reducing surface states, high energy hydrogen implants may cause damage to certain sensitive CMOS structures, particularly the gate oxide.

Various embodiments provide an ion cutting method and apparatus to avoid the problems mentioned above, and provide an ultrathin integrated circuit and thin imager substrate, which allows a back side illumination structure which is functionally uniform, reproducible, and contains a very thin substrate imager collection area.

The thickness of the final silicon using the standard ion cutting method is primarily a function of the energy of the hydrogen implantation. The hydrogen implantation may be controlled to produce a cleaved thickness with variation less than a few tens of nanometers, which compares favorably to the micrometers of variation across a substrate using a grind back method. According to modeling by SRIM2006, an industry accepted shareware program which calculates implantation range statistics, implanting hydrogen into silicon to achieve a peak depth (Rp) of 2 μm requires an implantation energy of about 220 KeV, 4 μm requires about 375 KeV, and 8 μm requires about 620 KeV. Given a constant dose to generate the cleavage (about 5E16/cm2 is a typical dose), the higher energy will produce more lattice damage and defects in the CMOS structures, particularly the gate insulator. Various embodiments provide ways to reduce the energy required for an ion cut.

One way to reduce this energy for a back side illumination imager is to build the imager with a thinner silicon collection region. However, a thinner silicon collection region means that more incoming photons will not pass through enough collector material to generate acceptable numbers of charge carriers.

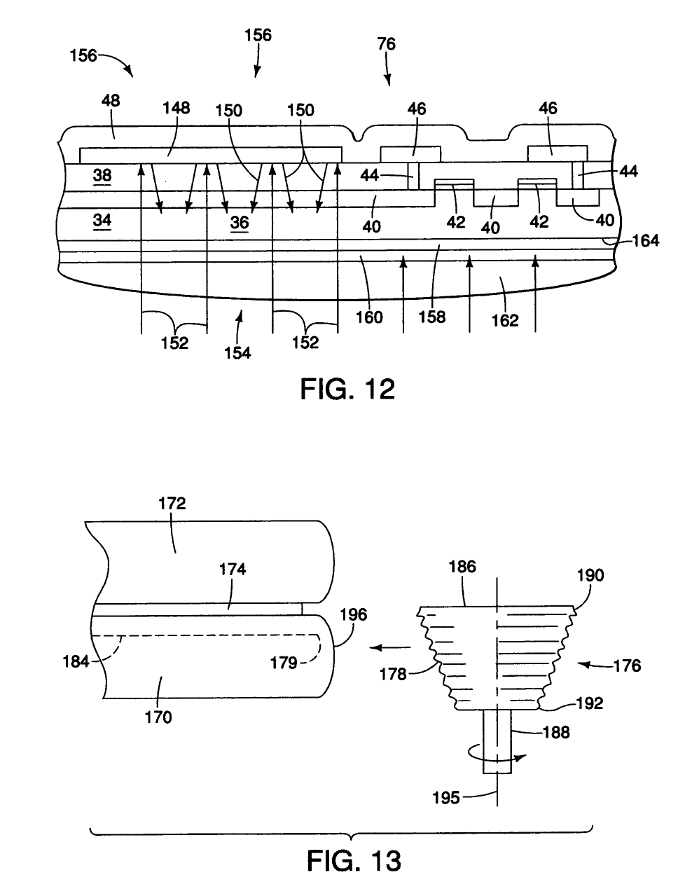

In order to restore the path length, in some embodiments (see FIG. 12), the metal coverage area on the front side 76 is intentionally increased. The extra metal 148 acts as a reflective surface to increase the path length through the silicon by reflecting 150 photons 152 which passed through the silicon, to travel again through the silicon towards the back surface 154, as shown in the cross-section of a pixel 156 in FIG. 12. This doubles the effective thickness of the silicon. FIG. 12 also shows components shown in FIG. 2, like reference numerals indicating like components.

More particularly, in FIG. 12 a substrate 34 (e.g., a P− substrate) is provided, a collection region 36 is defined, and there is a dielectric layer 38 over the substrate 34. Reference numeral 40 points to source/drain regions (e.g., N+ regions), reference numeral 42 points to transistor gates, reference numeral 44 points to contacts, and reference numeral 46 points to a standard metallization layer. In some embodiments, the extra metal (reflector metal) 148 is formed at the same time as at least some of the standard metallization 46. In front side illumination designs (see, U.S. Pat. No. 6,815,787 to Yaung et al., incorporated herein by reference), it is a goal to make the metal as small as possible in the photon collection region of each pixel. In the illustrated back side illumination embodiment, extra patches of metal 148 are added, at least over the photon collection region. More metal is formed than is required for electrical connectivity. In some embodiments, the front side of each pixel photon collection area has as much metal as possible except that, to minimize unwanted crosstalk between pixels, space without metal is provided between adjacent pixel photon collection areas. The extra metal does not need to be electrically connected to the metallization 46; however, in some embodiments, the size of standard metallization 46 is increased instead of or in addition to the provision of extra metal. In some embodiments, a majority of the area over the photon collection region is covered with metal 46 and/or 148. The reflector metal 148 ends in places to make room for the multiple interconnect metal lines which must connect to each pixel. Exactly how many pixels could be covered by a single patch of extra metal 148 can vary depending on the layout of the interconnect metal lines and contacts. FIG. 12 also shows an antireflective coat 158 on the backside, a color filter array 160 on the antireflective coat, and a microlens 162 on the color filter array.

Aluminum metallization is commonly used in imager construction and aluminum is an excellent reflector for visible, infrared and ultraviolet light. Thus, in some embodiments, aluminum is used for at least one of metallization 46 and the extra metal 148. Additionally, this conductive photon reflector may also be electrically coupled to biasing circuitry and, in operation, have a voltage applied relative to the substrate 34, or relative to back side conductive layer 164, in order to improve the collection of charge carriers at the front side 76. This biasing may be done individually by pixel, or as a single connected conductor plate for multiple pixels at the same time. The biasing may be pulsed so that it doesn't interfere with pixel readout operations. If the thickness requirement of the collector can be made thin enough, alternative lower energy and lower cost implantation techniques such as plasma immersion ion implantation may be used. Plasma immersion ion implantation energy is typically less than 100 KeV in equipment available today.

For the standard ion cutting process, after the hydrogen implantation it is necessary to attach the stiffener and then apply heat greater than 500 C to form microbubbles which cause exfoliation. If the heat is applied without the stiffener, then uncontrolled blistering will occur, rather than controlled cleaving at a plane within the substrate. If lower temperatures are applied after implant, in the range of 200-400 C, then much of the hydrogen escapes via diffusion and cannot be used to form microbubbles to achieve thermal exfoliation. It has been reported that a 5E16/cm2 dose produces maximum lattice damage in silicon, and that a higher dose allows lattice relaxation from platelets to microcracks (see, for example, S. W. Bedell, W. A. Lanford, Investigation of Surface Blistering of Hydrogen Implanted Crystals, 2001, Journal of Applied Physics, 90, 3, 1138, incorporated herein by reference). By carefully controlling the implantation dose and subsequent heat treatments as described herein, it is possible to generate the damage region and be able to reduce or eliminate the subsequent thermal exfoliation, yet still allow a mechanical exfoliation. Mechanical cleavage may be accomplished by inserting a knife edge, or even a high pressure gas knife at the “V” formed between the implanted substrate and the stiffener bonded to the substrate (see, for example, K. Henttinen, I. Suni, S. S. Lau, Mechanically Induced Si Layer Transfer in Hydrogen-implanted Si Wafers, 2000, Applied Physics Letters, 76, 17, 2370, incorporated herein by reference). A new, alternative cleaving embodiment described herein is a process called delayed exfoliation, which separates the implantation and cleaving processes to allow intermediate thermal processing steps while avoiding blistering, thereby making the cleaving process more versatile and useful. An implanted defect layer that allows for delayed exfoliation is provided in some embodiments.

One use for delayed exfoliation is to perform the hydrogen implantation immediately following the last high temperature diffusion step in the process, which is usually the formation of the CMOS gate structures, and then use the delayed exfoliation anneal to prevent blistering, and allow a high temperature anneal to repair the silicon-oxygen or silicon-silicon bonds which were damaged by the high energy hydrogen implantation. In an alternate embodiment of delayed exfoliation, the implantation is moved all the way to the beginning of the CMOS process flow, and even during substrate formation, to achieve a damaged lattice layer deep enough in the substrate to be below the CMOS devices during processing. This creates no CMOS device damage, because the CMOS processes all occur after the hydrogen implantation. The subsequent high temperature processing steps may repair any general substrate damage done by the implant, although a special anneal for this purpose may be needed. The defect layer is maintained by minimizing the process steps with temperatures above 800 C, or by generating enough lattice defects and microcracks at the implantation step that they are not able to be repaired by temperatures higher than 800 C.

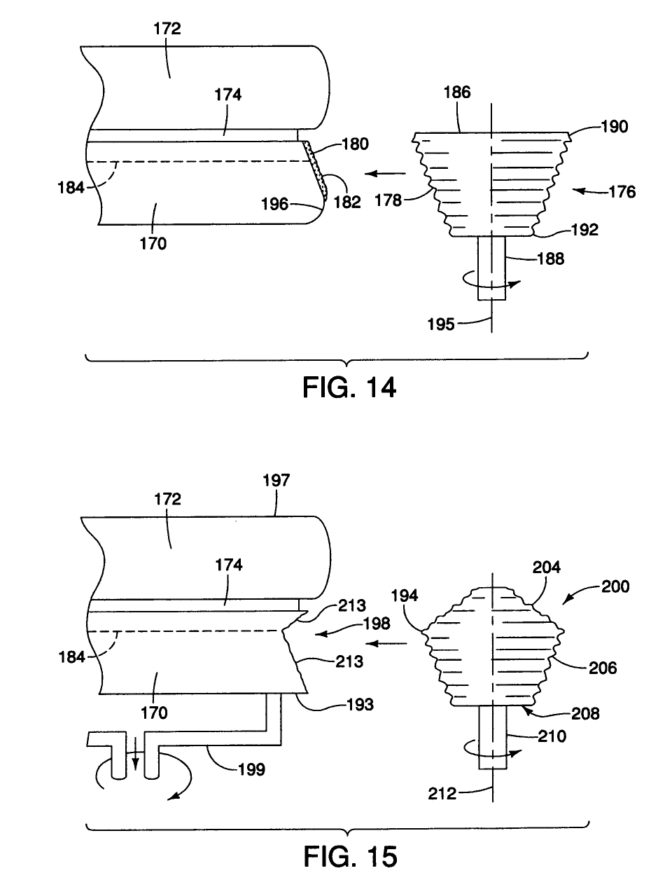

An alternative embodiment to optimize the final cleavage in standard or delayed exfoliation process is to generate large numbers of edge microcracks by grinding or abrading the edge of the implanted substrate. Substrate manufacturers normally etch and stress relieve the edges of the substrate to prevent accidental breakage. This makes the exfoliation process for planar cleavage difficult to initiate. Also, if the defect layer edge does not intersect the substrate edge, the cleavage is even more difficult to initiate. The stress relieved substrate edge and the gap between the defect layer and the substrate edge combine to make the delayed exfoliation process more stable and less likely for premature cleavage to occur. This added stability increases the necessity for the microcrack formation process to be used when cleavage is desired. FIG. 13 shows a method and apparatus to generate large numbers of edge microcracks, which cross the implanted lattice damage region. More particularly, FIG. 13 shows an implanted substrate 170, such as a substrate for an integrated circuit, bonded to a stiffener or handler substrate 172 by a bond 174. Also shown is a defect layer 184, and a defect layer edge 179 which does not intersect substrate edge 196. An abrasion tool 176 having a rough surface 178 is used to create microcracks 180 and a rough surface 182 on the substrate (see FIG. 14). In the illustrated embodiment, the microcracks 180 are created proximate the implanted defect layer 184. In the illustrated embodiment, the abrasion tool 176 has a head 186 on a chuck 188. The head 186 has an end 192 proximal the chuck 188, and a distal end 190 with a diameter greater than the diameter of the proximal end 192. In the illustrated embodiment, the head 186 has a frustroconical shape. Other shapes could be employed. In the illustrated embodiment, the head 186 rotates, in operation, about an axis 195 defined by the chuck 188 to abrade the edge 196. As seen in FIG. 14, the edge 196 is selectively abraded to have a rough abraded edge 182. In addition, the non-defect region between the original substrate edge 196 and the defect layer edge 179 shown in FIG. 13, has been removed by the abrasion process shown in FIG. 14, to provide a lower cleavage initiation energy.

Subsequent to the generation of edge microcracks, a stiffener, a knife edge, or a gas knife is used to cleave the substrate. The generation of microcracks significantly reduces the amount of force required for the cleaving. This structure is shown in FIGS. 13 and 14, before and after abrasion, respectively. The substrates may be rotating or stationary. This edge microcrack process may lower the hydrogen dose required, the stiffener bond force required for the bond 174, and the cleaving temperature requirement.

In an alternative embodiment, shown in FIG. 15, to achieve cleavage after the formation of a damaged or stressed layer 184 (and, optionally, after formation of the microcracks 180), bottom surface 193 of a substrate 170, which is round in the embodiment of FIG. 15 when viewed from above or below, is placed on a rotatable vacuum chuck 199, alternatively with vacuum applied to a top surface 197 of the joined substrates 170 and 172. An edge 194 of a rotating mechanical knife (or cutting or abrasion) tool 200 is applied to the substrate 170. In some embodiments, the knife 200 is built using a diamond impregnated blade, or other abrasive system. In some embodiments, the knife 200 rotates, in operation, at a different rate or opposite direction from the substrates 170 and 172 and thereby abrades material from the substrate 170 at, or near the cleavage plane 184. In FIG. 15, the abrasion tool or knife 200 has rough surfaces 204 and 206 on a head 208 configured to rotate with a chuck 210 about an axis 212. The surfaces 204 and 206 form the shape of a sideways “V”, in side view, that rotates about the axis 212 in operation. This avoids the problem of needing a “V” shape or crevice between the stiffener and the substrate, and takes advantage of the edge grinding formation of edge microcracks as mentioned previously, and may not need to have a stiffener present to achieve cleavage. Thus, in some embodiments, the stiffener 172 is omitted. With the abrasive knife edge, a “V” 213 is abraded directly in the substrate 170 around the perimeter 198. After the V is formed, either the abrasive knife edge or a smooth rotating knife edge or gas knife is used to complete the cleavage, if necessary.

It is to be understood that there are other methods besides hydrogen implantation to achieve a defect layer in the substrate, such as implantation of other ions such as helium, oxygen, argon, nitrogen, silicon, and germanium, or the addition of a layer with other elements, such as Si/Ge, a layer of porous silicon, or an interlayer of silicon dioxide, which may be used to cleave and form integrated circuit structures as described herein.

An additional advantage for back side illumination and other type of integrated circuits is the potential to use an additional doped semiconductor layer, which is then generated on the back side surface after thinning of the silicon. A back side doping layer of N or P type, depending on the substrate type, may be applied after cleaving using, for example, ion implantation, plasma ion immersion implantation (Pill) or doped oxides with laser assisted diffusion or rapid thermal processing after the thinning of the substrate is completed. Alternatively, a doped layer may be generated by using a substrate with a special doped layer epitaxially grown and positioned at the appropriate depth so that after the cleaving process, the doped layer will be in the correct position relative to the cleaved surface.

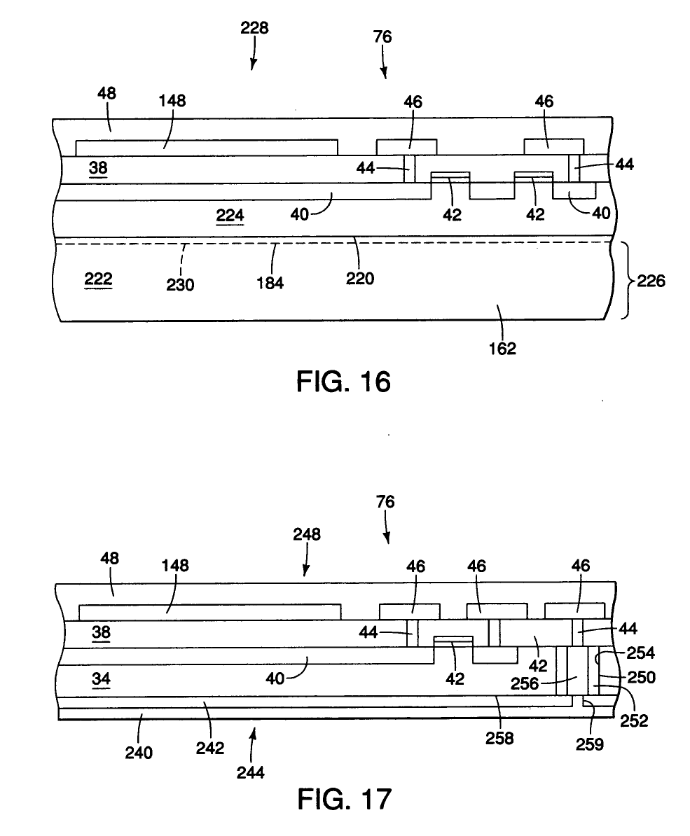

For example, as shown in FIG. 16, if a heavily doped layer 220 (e.g., boron, 1 μm thick) is desired at the light entry surface of a lightly doped (e.g., boron, 3 μm thick) final imager structure, a substrate 222 (e.g., a P+ substrate), and then a lightly doped layer 224 (e.g., boron, 3 μm thick) is epitaxially grown on top. The epitaxial layer 224 may be grown either before or after the implantation and formation of the defect layer 184 in the substrate. The energy required for an implantation after an epitaxial layer 224 is formed would be greater than without an epitaxial layer, but implantation after the formation of the layer 224 is possible. If a thick (e.g., greater than 2 μm) collection region 36 is required, the defect layer 184 is, in some embodiments, formed prior to formation of the epitaxial layer 224. This allows any thickness of epitaxial layer to be used without requiring a difficult high energy implantation. Reference numeral 40 points to source/drain regions (e.g., N+ regions), reference numeral 42 points to transistor gates, reference numeral 44 points to contacts, and reference numeral 46 points to a standard metallization layer. After removing the back side substrate material 226 to leave only 4 μm of the original silicon and epitaxial layer, and the 1 μm heavily doped boron region 220 is at the new surface 230. A cross-section of this structure 228 before the cleave is shown in FIG. 16. This heavily doped layer will assist in the collection of charge carriers generated by photons and improve the collection efficiency and reduce crosstalk between pixels, which will improve resolution. An additional benefit is the gettering of the hydrogen at the highly defective region. This prevents the hydrogen from travelling to other doped regions near the source and drain (S/D) of devices, which could have a deleterious effect on them. The heavily doped region is located between the heavily defective region and the MOS devices, and in some embodiments is contained within the defective lattice region as well. This structure, with a heavily doped layer at the same surface as the incoming light, is based on a technique that cannot easily be used with conventional MOS integrated circuits, due to the need to build MOS devices into lightly doped silicon on the front surface of the silicon layer.

In another embodiment, shown in FIG. 17, a conductive layer 240, with or without an insulator 242 such as silicon dioxide or silicon nitride between the conductor and the substrate 34, is placed on the back side 244. The conductive layer 240 is, in some embodiments, a very thin layer, e.g., less than 50 nm, so as to be somewhat transparent (e.g. greater than 50% transmission of light) for use with back side illuminated imager integrated circuit, and is of a metal such as aluminum or gold, or a thicker layer of conductive transparent material such as doped indium tin oxide or zinc oxide. The purpose of the conductive layer 240 is to allow an electrical bias to be applied relative to the substrate 34 or relative to the surface devices to improve charge collection and electrical performance. The conductive layer 240 may be contacted directly from the front side 248 with a wire bond or similar contact method. Alternatively, and more advantageously for a wafer level packaging approach, the conductive layer 240 is contacted from the front side 248 through a previously prepared through-substrate via (TSV) structure 250 implemented from the front side 248 during integrated circuit processing or implemented from the back side after the cleave. The via 250 may be made, for example, by etching or laser drilling a hole into the substrate 34 down below the final thickness 258 expected after the subsequent thinning process, and depositing an insulator 252 on the sidewall 254, such as silicon dioxide. Then, a conductor 256 of material such as nickel, gold or aluminum is plated and/or deposited into the via 250. The vias are typically filled with the conductor material, or an additional insulator material may be used to eliminate any voids. The conductor 256 is coupled to the front side metallization 46 to be later coupled to circuits to control the bias placed on the transparent conductor 240 during operation. In the illustrated embodiment, the formation and connection of the transparent conductor 240 is accomplished after the thinning operation. If an insulator 242 is provided (e.g., deposited) on the back side, the via contact or conductor 256 is exposed, e.g., by photolithography. If there is no insulator on the back side, then the insulator 252 and the via conductor 256 may be exposed, e.g., by chemical mechanical planarization (CMP) or by wet etch. An example chemistry for wet etch would be dilute HF to remove a silicon dioxide insulator. FIG. 17 is a cross-section of an imager die at a pixel site, with a via and back side transparent conductor and back side insulator in place. In the case of a non-optical integrated circuit, the back side conductor does not have to be transparent.

Instead of using a continuous back side conductor, in some embodiments, multiple conductors are patterned into individual segments, with respective conductive segments tied to respective pixels or regions through separate vias. This allows the bias of each pixel or memory cell or electrical device capture region to be controlled separately from its neighbors, and may be varied as needed to minimize crosstalk between regions and to maximize charge collection efficiency. Alternatively, the bias may be the same for certain regions, such as a common color pixel for image sensors, and therefore the conductors under the common color could be connected to each other and would not require a via for each pixel. For these embodiments, the structure in FIG. 17 is duplicated for every pixel or region requiring a back side conductor connection.

Additionally, if an insulator is provided between the silicon and the conductive material on the back side, the insulator, in some embodiments, is used as an antireflective coating, and may be composed of a single layer, such as silicon nitride, or various layers of materials, such as alternating thin layers on the order of 5-300 nm thick, of silicon dioxide and titanium dioxide.

In an alternate embodiment as shown in FIG. 13, in order to minimize breakage or premature cleavage during processing subsequent to the defect layer formation, it may be beneficial to create a defect layer 184 in the substrate 170 wherein the defect layer has at least one edge 179 which does not intersect the substrate edge 196. This provides for non-defect regions within the defect layer plane at specific locations. By preventing the defect layer from being continuous from edge to edge of the substrate in all diameters, the energy required to initiate cleavage increases, and therefore the substrate is less likely to cleave prematurely by mechanical contact or thermal stress. Providing non-defect regions at the substrate perimeter is particularly effective to prevent premature cleavage, because the edge of the substrate is where the cleavage is the easiest to initiate. The gap between the substrate perimeter edge and the defect layer is greater than 1.0 um. These non-defect regions may be formed by providing means to prevent the defect layer implantation from occurring uniformly across the first surface of the substrate. The intentional initiation of cleavage for a substrate with a defect layer which does not intersect the substrate perimeter utilizes the same mechanical, thermal, etching, and grinding methods as described for a defect layer which does intersect the substrate perimeter. However, more cleavage energy may be required, and grinding further into the substrate edge may be required to ensure the microcracks 180 intersect the defect layer 184 as shown prior to grinding in FIG. 13, and after grinding in FIG. 14.

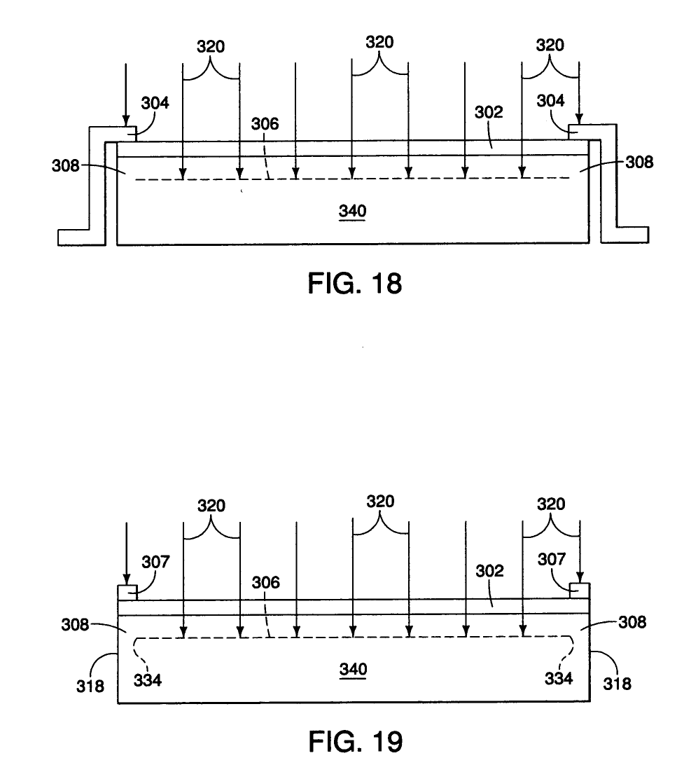

For example, in one embodiment, shown in FIG. 18, an integrated circuit substrate 340 having an oxide layer 302 is receiving a hydrogen ion implantation process step 320 to create a defect layer. The implantation is physically blocked around the substrate perimeter by a clamping ring 304 of sufficient thickness (i.e. greater than 100 um for stainless steel), which is held proximate the external surface of the oxide layer during implantation, and results in a defect layer 306 in the central region of the substrate, and a non-implanted region 308 correlated to the clamping ring 304 at the substrate perimeter. This defect layer is not continuous across all diameters from substrate edge to opposite substrate edge. The clamping ring would typically be incorporated as part of the implanter tooling, but may also be a separate structure from the implanter.

In an additional embodiment, shown in FIG. 19, an integrated circuit substrate 340 having an oxide layer 302 is receiving a hydrogen ion implantation process step 320 to create a defect layer. The implantation is physically blocked around the substrate perimeter 318 by a masking material 307 adhering to the oxide layer, and results in a defect layer 306 in the central region of the substrate, and a non-implanted region 308 correlated to the masking material at the substrate perimeter. The masking material is composed of photoresist or other materials known in the art to block ion implantation for the specific species being implanted and the implantation energy used. For example, a 2 um layer of hardened photoresist will block a 50 KeV hydrogen implantation. The pattern of the mask may be altered to produce the desired defect shape.

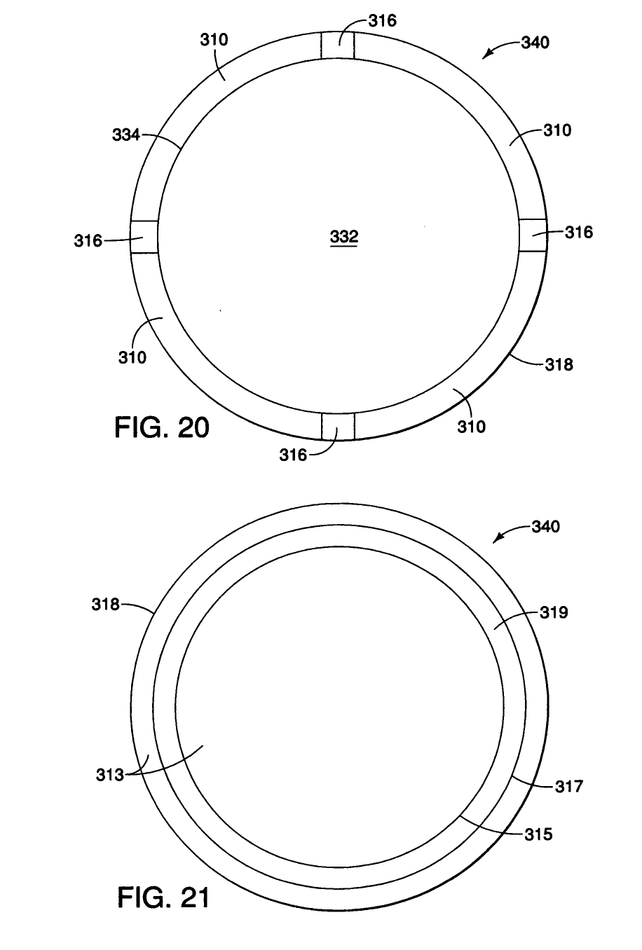

For example, in one embodiment, shown in FIG. 20, the substrate 340 is patterned with a defect implantation mask 310, comprised of 4 sections, to block the implantation near the substrate perimeter 318. The substrate center region 332 and 4 small regions 316, comprise the implanted defect layer area, and the outer portions of the 4 small regions 316 do intersect the substrate perimeter 318. This defect layer will have a cleavage energy between the cleavage energy of the embodiment with full intersection of the defect layer with the substrate edge, and the cleavage energy of the embodiment with no intersection of the defect layer and the substrate edge. Defect layer structures with intermediate amounts of edge intersection allow for tuning the energy required for cleavage.

In an additional embodiment, shown in FIG. 21, the substrate 340 is patterned with a defect implantation mask 313 to block the defect layer in the substrate center and at the perimeter of the substrate 318, thereby forming a defect layer in the shape of an annulus 319 with inner 315 and outer 317 defect layer edges. The annulus defect layer does not intersect the substrate edges and the absence of a defect layer at the substrate edge and in the substrate center minimizes both premature cleavage and warpage or surface deformation. Warpage or surface deformation may interfere with standard semiconductor processing steps, such as photolithography. In some embodiments, to lower the energy of cleavage, portions, or all, of the defect layer 319 may extend to the edge of the substrate perimeter 318. Additionally, there may be multiple non-defect regions inside the outer boundary 317 of the defect layer.

In an additional embodiment, the location of the defect layer formed under the surface of the substrate, may not be visible using standard methods of visual inspection, if the defect layer mask is removed after implantation. The location of the defect layer edges may be determined by referencing the defect layer edges to physical markers on the substrate, such as a flat or notch in the edge of the substrate, or by patterns put onto the substrate during integrated circuit processing.

In an additional embodiment, for those integrated circuits which require epitaxy, the epitaxy formed over a defect layer containing non-defect regions will have fewer crystalline defects than epitaxy formed over a continuous defect layer. Reducing crystalline defects is generally beneficial to integrated circuit performance. Providing smaller areas of defect layer in the substrate will reduce epitaxial crystalline defects.

In an alternate embodiment, the formation of a patterned defect layer may be accomplished by the direct write of the ion implantation beam, rather than a blocking or masking of the beam. Ion implantation beams may be steered electromagnetically to leave regions on the substrate unimplanted.

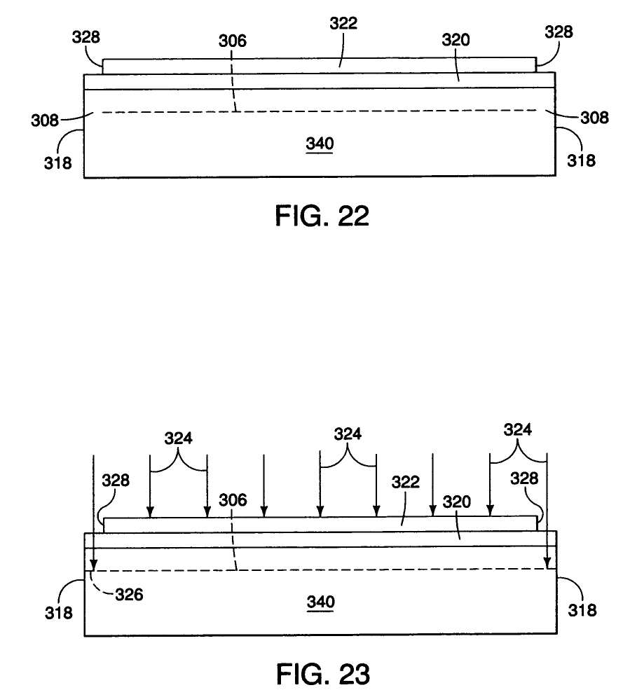

In an alternate embodiment shown in FIG. 22, after forming a first defect layer 306 which does not intersect the substrate perimeter 318 and completing all of the integrated circuit process steps which have a high risk for premature cleavage, it may be preferable to lower the energy required for cleavage. This is accomplished by providing a second defect implantation 324 prior to the cleavage process, which is formed primarily where the first defect layer is absent at the substrate perimeter. The substrate 340 is shown after the formation of the first patterned defect layer 306 and the formation of the epitaxial layer and the integrated circuit electrical devices 320. A second ion implantation mask 322, composed of photoresist or other implantation masking materials which are known in the art to be thick enough to block the second ion implantation, is patterned with essentially opposite polarity to the pattern of the first defect implantation mask 307 in FIG. 19. FIG. 23 shows the second defect layer ion implantation 324 into substrate 340 and through epitaxial layer 320, to form a second defect layer 326 which bridges the non-defect layer gap 308 in FIG.22, and forms a continuous defect layer, comprised of both defect layers 326 and 306, to the substrate perimeter 318. The second defect layer ion implantation 324 will typically be higher energy than the first defect layer ion implantation due to the thickness of the substrate increasing through the process steps, and substantially the same dose as the first defect layer ion implantation. The second defect layer ion implantation energy will be less than 10 MeV. An anneal may be required after the second defect layer ion implantation to fully form the second defect layer.

### Part 3, Integration

After the cleaving, the integrated circuit substrate may be completed with the formation of solder balls, or other attachment structures, and singulated. However, additional processing such as wafer level packaging for stacking of integrated circuits, or imager camera formation for a CMOS image sensor may be desirable prior to singulation.

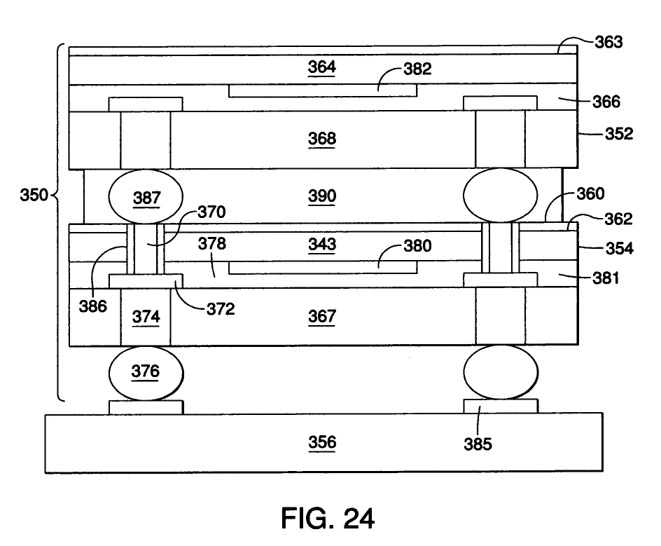

As example only, a full sequence for constructing a very specific complete stacked package device 350 in accordance with some embodiments, is shown in cross-section in FIG. 24. The package contains two dice 352 and 354, and only the bottom die 354 contains a through-substrate via 386. With the exception of the through-substrate via, the process sequence below applies to both dice, and the through-substrate via does not alter the essential steps for thinning the substrates.

1) Start with a highly doped P+ silicon substrate 340 (see FIG. 18).

2) Grow an initial 0.1 um thermal oxide 302 (see FIG. 18).

3) Using plasma immersion ion implantation, implant hydrogen 320 at 40 KeV with a dose of 2E16 ions/cm2, and implant helium 320 at 48 KeV with a dose of 2E16 ions/cm2, into the substrate 340, except for a 2 millimeter substrate perimeter region 308 which is blocked by the clamp 304 during implantation. This process initiates a defect layer 306 (see FIG. 18).

4) Anneal at 400 C for 180 min.

5) Strip the implantation oxide and cap with a 10-20 ohm-cm, 5 um thick epi layer with a resistivity of about 10 ohm-cm. Process the substrate through an MOS device formation sequence and stop just prior to top (front side) metal deposition. In other words, perform oxidation, patterning, etching, and other semiconductor processing steps on silicon substrates 364 and 343 to form active MOS devices in the silicon (see FIG. 24).

6) Form the through-substrate vias 254, by first patterning and etching holes at the future connection points to the back side conductor. Then deposit an insulator 252 and conductor 256, and remove excess conductor and insulator from the front side by CMP (see FIG. 17).

7) Perform top metal deposition and patterning, to provide metallization 46 and cover with low temperature plasma oxide resulting in passivation layer 48 shown in FIG. 17. Plasma oxide is only one example of a material that can be used to define a passivation layer. Other low temperature oxides are possible, as are plasma silicon nitride and stacks of oxide and nitride.

8) Pattern openings for the bond pads 66 and any required through-substrate via pads and electrolessly form 50 um tall Ni/Au bumps 78/80 on the bond pads (see FIG. 3).

9) Encapsulate the front side with glass filled molding encapsulation 82, leaving the bumps exposed (see FIG. 3).

10) Temporarily attach a carrier substrate to the front side with adhesive or electrostatically. This allows a thinner encapsulation 82 to be used (see FIG. 3).

11) Rotationally abrade the edge 196 (see FIG. 13) of the substrate with an abrasive knife edge 194 at a defect layer 184, with vacuum and tension applied to top surface 197 and bottom surface 193 until cleavage occurs (see FIG. 15).

12) Lightly perform CMP (chemical mechanical planarization) on the back side surface 258 after the cleave to smooth the surface 258 and to make the vias 254 flush with the back side surface 258 (see FIG. 17).

13) Deposit a silicon dioxide insulator 242 on the back side and photolithographically pattern and etch openings 259 in the insulator at the appropriate through-substrate via locations to allow contact to the through-substrate via conductor 256 (see FIG. 17).

14) Remove the temporary carrier and form solder balls 376 and 387 on the front side bumps (see FIG. 24).

15) Singulate using wafer sawing.

16) Align the top die 352 (the die without through-substrate vias) with the solder balls 387 against the bottom die 354 and contacting the through-substrate vias of die 354, and heat to allow the solder to form an electrical connection (see FIG. 24).

17) Repeat step 16, if required to stack more dice in a single package.

18) Fill the gaps between dice with a glass-filled polymer 390 (see FIG. 24).

19) Cure the glass-filled polymer 390 (see FIG. 24).

20) Attach completed stacked package 350 to printed circuit board 356 (see FIG. 24).

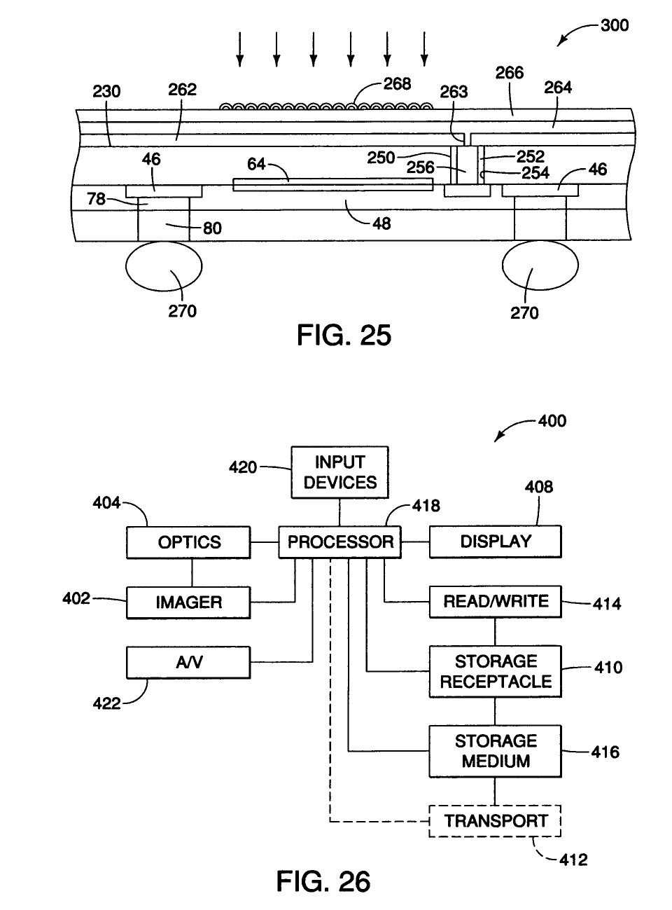

After the cleaving (and optional smoothing), the imager wafer front side is substantially packaged, and the back side surface is very flat and smooth, and an antireflective coating, color filter arrays, and micro lenses are formed, in some embodiments. A full sequence for constructing a very specific complete wafer level imager device 300 in accordance with some embodiments will now be described, as example only, which results in a completed CMOS imager die as shown in cross-section in FIG. 25.

1) Start with a highly doped P+ silicon substrate 122 capped with a 10-20 ohm-cm, 2 μm thick epi layer (see FIG. 9)

2) Grow an initial 0.1 μm thermal oxide 302 and implant (See FIG. 18) hydrogen 320 at 225 KeV at a dose of 5E16/cm2 to into the substrate 340, except for a 2 millimeter substrate perimeter region 308 which is blocked by the clamp 304 during implantation. This process initiates a defect layer 306.

3) Anneal at 400 C for 180 min.

4) Strip the implantation oxide, process the wafer through CMOS imager flow and stop just prior to top (front side) metal deposition. In other words, perform oxidation, patterning, etching, and other semiconductor processing steps on a silicon substrate 122 to form active MOS devices in the silicon (see FIG. 9).

5) Form the through-substrate vias 254, by first patterning and etching holes at the future connection points to the back side conductor. Then deposit an insulator 252 and conductor 256, and remove excess conductor and insulator from the front side by CMP (see FIG. 17).

6) Perform top metal deposition and patterning, to provide metallization 46 and extra metal 148 and cover with low temperature plasma oxide resulting in passivation layer 48 shown in FIG. 17. Plasma oxide is only one example of a material that can be used to define a passivation layer. Other low temperature oxides are possible, as are plasma silicon nitride and stacks of oxide and nitride.

7) Pattern openings for the bond pads 66 and electrolessly form Ni/Au bumps 78/80 on the bond pads (see FIG. 3).

8) Encapsulate the front side with glass filled molding encapsulation 82, leaving the bumps exposed (see FIG. 3).

9) Rotationally abrade the edge 196 (see FIG. 13) of the wafer with an abrasive knife edge 194 at a defect layer 184, with vacuum and tension applied to top surface 197 and bottom surface 193 until cleavage occurs (see FIG. 15).

10) Lightly perform CMP (chemical mechanical planarization) on the back side surface 230 after the cleave to smooth the surface 230 and to make the vias 254 flush with the back side surface 230 (see FIG. 25).

11) Deposit a silicon nitride antireflective coating 262 on the back side 230 and photolithographically pattern and etch openings 263 in the antireflective coating to allow contact to the conductors 256 in the through-substrate vias 254.

12) Deposit a layer of indium tin oxide 264 on the antireflective coating 262, to form the back side conductor 264, and pattern into individual conductive elements over each pixel.

13) Form the color filter array 266 on the back side conductor.

14) Form the microlenses 268 on back side color filter array 266.

15) Form the solder balls 270 on front side.

16) Singulate using wafer sawing.

Inserting wafer level optics processing between items 14 and 15 above to build a wafer level camera structure is an option allowed by this method.

FIG. 26 illustrates a still or movie camera 400 in accordance with various embodiments. The camera 400 includes an imager or imager device 402, manufactured in accordance with any of the above methods. The camera 400 further includes optics 404, such as a lens and/or aperture, that, when opened, casts an image on the imager 402. The camera 400 further includes a display 408 for showing images being captured by the camera 400 or that were previously captured by the camera 400 or by another device. The display 408 is a touch screen in some embodiments. The camera 400 further includes a receptacle 410 for a storage medium or media 416 which is solid state memory such as a memory card or stick, in some embodiments, or some other form of storage in other embodiments. The camera 400 may have additional on-board storage, if desired. If the storage medium or media 416 includes moving parts, such as a tape, disk, or hard drive (e.g., in the case of a movie camera), the camera 400 further includes a transport 412 for advancing the storage medium 416. The camera 400 further includes a read/write mechanism 414 for reading from or writing to the storage medium, via the storage receptacle 410, or for reading from or writing to on-board storage. The camera further includes input devices 420 such as control switches and a button for selectively capturing an image. Audio-video inputs and outputs 422 for cables may also be included. The camera 400 further includes a receptacle for a power source, such as a battery (not shown) or a coupling for a power cable (not shown). The camera 400 further includes a processor 418, or other control circuitry, coupled to the imager 402, input devices 420, transport 412, read/write mechanism 414, storage receptacle 410, and display 408, for controlling operation of the camera 400.

In compliance with the patent statutes, the subject matter disclosed herein has been described in language more or less specific as to structural and methodical features. However, the scope of protection sought is to be limited only by the following claims, given their broadest possible interpretations. The claims are not to be limited by the specific features shown and described, as the description above only discloses example embodiments.

I/we claim:

1. A method of manufacturing an integrated circuit, the method comprising:
providing a substrate having a front side, a back side, and an edge extending from the front side to the back side;
creating a defect layer in the substrate, the defect layer having at least one edge which does not intersect the edge of the substrate;
defining a semiconductor device proximate the front side after creating the defect layer; and
cleaving proximate the defect layer after defining the semiconductor device.

2. A method in accordance with claim 1 wherein creating the defect layer comprises performing an ion implantation.

3. A method in accordance with claim 1 wherein creating the defect layer comprises performing an ion implantation using an ion selected from the group consisting of hydrogen, helium, oxygen, silicon, argon, nitrogen, and germanium.

4. A method in accordance with claim 1 wherein creating the defect layer comprises blocking the ion implantation in localized regions.

5. A method in accordance with claim 4 wherein the blocking comprises attaching a masking material to the substrate.

6. A method in accordance with claim 4 wherein the blocking comprises using a mechanical clamp.

7. A method in accordance with claim 2 wherein the ion implantation is performed using a steerable implantation beam and wherein creating the defect layer comprises steering the implantation beam to provide non-implanted regions.

8. A method in accordance with claim 1 wherein the defect layer is in the shape of an annulus.

9. A method in accordance with claim 1 wherein the defect layer is in the shape of an inverse annulus.

10. A method in accordance with claim 1 wherein the defect layer has regions extending to the edge of the substrate, and regions which do not extend to the edge of the substrate.

11. A method in accordance with claim 1 and further comprising generating microcracks relative to the edge, proximate the defect layer, using an abrasion tool.

12. A method in accordance with claim 11 wherein the abrasion tool has a head and wherein generating the microcracks comprises rotating the head of the abrasion tool.

13. A method in accordance with claim 11 and further comprising generating a notch in the edge using a tool having the general shape of a sideways V that is rotatable about an axis.

14. A method in accordance with claim 1 and further comprising performing a metallization after creating the defect layer.

15. A method in accordance with claim 1 and further comprising providing through-substrate vias from the front side, prior to the cleaving, for use in electrically coupling devices from the back side to the front side.

16. A method in accordance with claim 1 and further comprising providing through-substrate vias from the back side, after the cleaving, for use in electrically coupling devices from the back side to the front side.

17. A method in accordance with claim 1 and further comprising providing a stiffener on the front side, prior to the cleaving, and providing holes in the stiffener for electrical connections.

18. A method in accordance with claim 17, the method further comprising bonding the stiffener to the front side, and providing the holes in the stiffener prior to the bonding.

19. A method in accordance with claim 17, the method further comprising bonding the stiffener to the front side, and providing the holes in the stiffener after the bonding.

20. A method in accordance with claim 17 and further comprising encapsulating the front side with a stiffener material, prior to the cleaving.

21. A method in accordance with claim 17 and further comprising defining saw streets in the substrate, and partially encapsulating the front side, over the saw streets, prior to the cleaving.

22. A method in accordance with claim 1 wherein the integrated circuit that is manufactured performs at least one function selected from the group consisting of microprocessor, memory, image sensor, gate array, and RFID.

23. A method of manufacturing an integrated circuit, the method comprising:
providing a substrate having a front side, a back side, and an edge extending from the front side to the back side;
creating a first defect layer in the substrate, the first defect layer having at least one edge which does not intersect the edge of the substrate;
defining a semiconductor device proximate the front side after creating the defect layer;
creating a second defect layer in the substrate, the second defect layer being substantially in the same plane as the first defect layer, and having at least one edge intersecting the edge of the substrate, and;
cleaving proximate the second defect layer, after creating the second defect layer.

24. An integrated circuit formed from a method comprising:
providing a substrate having a front side, a back side, and an edge extending from the front side to the back side;
creating a defect layer in the substrate, the defect layer having at least one edge which does not intersect the edge of the substrate;
generating microcracks relative to the edge, proximate the defect layer, using an abrasion tool; and
cleaving proximate the defect layer after generating the microcracks.

25. An integrated circuit in accordance with claim 24 wherein creating the defect layer comprises performing an ion implantation.

26. An integrated circuit in accordance with claim 24 wherein creating the defect layer comprises blocking the ion implantation in localized regions.

27. An integrated circuit in accordance with claim 26 wherein the blockage is performed by a masking material attached to the substrate.

28. An integrated circuit in accordance with claim 26 wherein the blockage is performed by a mechanical clamp.

29. A method comprising:
providing a substrate having a front side and a back side, and an edge extending from the front side to the back side;
implanting an ion to create a defect layer in the substrate, the defect layer having at least one edge which does not intersect the edge of the substrate;
forming active MOS devices in the substrate including devices to define an integrated circuit;
forming through-substrate vias from the front side;
depositing insulators in the vias;
depositing conductors in the vias;
removing excess conductor and insulator from the front side;
covering the metal with a passivation layer;
patterning bond pad openings and electrolessly forming Ni/Au bumps electrically coupled to MOS devices;
at least partially encapsulating the front side;
abrading the edge with an abrasive knife edge at the defect layer and performing cleaving to provide a new backside surface;
smoothing the new back side surface and making the vias flush with the new back side surface;
forming an electrically insulating coating on the smoothed surface;
providing openings in the insulating coating to allow contact to the through-substrate vias.
